(19) United States
(12) Patent Application Publication
(10) Pub. No.: US 2008/0210958 A1
(43) Pub. Date: Sep. 4, 2008

(54) Semiconductor white light emitting device and method for manufacturing the same

(75) Inventors: Kazuhiko Senda, Kyoto (JP); Shunji Nakata, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/987,020

(22) Filed: Nov. 26, 2007

(30) Foreign Application Priority Data
Dec. 5, 2006 (JP) 2006-328285

(51) Int. Cl. H01L 33/00

(52) U.S. Cl. 257/89; 438/27; 257/E33.012

(57) ABSTRACT

A semiconductor white light emitting device including: a semiconductor light emitting element having green and blue light emitting layers containing In; and a phosphor capable of emitting red light.

### CROSS REFERENCE TO RELATED APPLICATIONS AND INCORPORATION BY REFERENCE

This application is based upon and claims the benefit of priority from prior Japanese Patent Application P2006-328285 filed on Dec. 5, 2006; the entire contents of which are incorporated by reference herein.

### BACKGROUND OF THE INVENTION

1. Field of the Invention

The present invention relates to a semiconductor white light emitting device including a semiconductor light emitting element having a plurality of light emitting layers capable of emitting light of different colors.

2. Description of the Related Art

A known conventional semiconductor white light emitting device includes a semiconductor light emitting element having a plurality of light emitting layers emitting light of different colors.

For example, Japanese Patent Laid-open Publication No. 2005-217386 (Patent Literature 1) discloses a first semiconductor white light emitting element including: a semiconductor light emitting device having a red light emitting layer capable of emitting red light and a blue light emitting layer capable of emitting blue light; and a package having a phosphor capable of radiating yellow-green light.

In the first semiconductor white light emitting device, when the semiconductor light emitting element is supplied with current, the red and blue light emitting layers emit red and blue light, respectively. The red light is transmitted through the package to be radiated to the outside without being changed. A part of the blue light is transmitted and radiated to the outside without being changed, and another part of the same is converted by the phosphor to yellow-green light and then radiated to the outside. The red, blue, and yellow-green light are thus mixed and radiated to the outside as white light.

Patent Literature 1 also discloses a second semiconductor white light emitting device including: a semiconductor light emitting element having an ultraviolet light emitting layer capable of emitting ultraviolet light and a blue light emitting layer capable of emitting blue light; and a package including two types of phosphors capable of radiating yellow-green and red light.

In the second semiconductor white light emitting device, when the semiconductor light emitting element is supplied with current, the ultraviolet and blue light emitting layers emit ultraviolet and blue light, respectively. By the phosphors, a part of the ultraviolet light is converted to the yellow-green light and then radiated to the outside while another part of the ultraviolet light is converted to red light and then radiated to the outside. A part of the blue light is radiated to the outside without being changed, and the other part thereof is converted by the phosphors to yellow-green and red light and then radiated to the outside. The red, blue, and yellow-green light are mixed and radiated to the outside as white light.

Herein, in the aforementioned first semiconductor white light emitting device of Patent Literature 1, the red light emitting layer emitting red light is composed of an InGaN layer. However, in order to allow the InGaN layer to emit red light, the ratio of In needs to be increased. However, increasing the ratio of In in the InGaN layer reduces the crystallinity and reduces the emission intensity of red light to below a desired emission intensity. The white light therefore is biased to a certain color, and an amount of white light is reduced.

In the aforementioned second semiconductor white light emitting device of Patent Literature 1, the two types of light such as ultraviolet and blue light are converted into the two types of light such as yellow-green and red light for radiation of white light. However, it is difficult to control the ratios of the two types of phosphors which convert ultraviolet and blue light to yellow-green and red light and to equally distribute the phosphors in the package, thus resulting in a problem that white light is biased to a certain color.

### SUMMARY OF THE INVENTION

A semiconductor white light emitting device according to the present invention includes: a semiconductor light emitting element having a green light emitting layer and a blue light emitting layer which contain indium (In); and a phosphor capable of emitting red light.

A method for manufacturing a semiconductor white light emitting device according to the present invention includes: a step of forming a semiconductor light emitting element having a green light emitting layer and a blue light emitting layer which contain In; and a step of covering the semiconductor light emitting element with a package which is made of synthetic resin capable of transmitting light in which a phosphor capable of emitting red light is blended.

According to the present invention, the semiconductor light emitting element includes the green and blue light emitting layers which have ratios of In smaller than that of a light emitting layer capable of emitting red light, so that both the light emitting layers can be increased in crystallinity. This can facilitate control of emission intensities of green and blue light to desired emission intensities. It is therefore possible to prevent white light from being biased to a certain color and increase an amount of white light.

### BRIEF DESCRIPTION OF DRAWINGS

FIG. 1 is a schematic view of a semiconductor white light emitting device according to a first embodiment of the present invention.

FIG. 2 is a cross-sectional view of a semiconductor light emitting element.

FIG. 3 is a cross-sectional view of light emitting layers of the semiconductor light emitting element.

FIG. 4 is a cross-sectional view of a semiconductor light emitting element according to a second embodiment.

FIG. 5 is a cross-sectional view of a semiconductor light emitting element according to a modification.

FIG. 6 is a cross-sectional view of a semiconductor light emitting element according to another modification.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

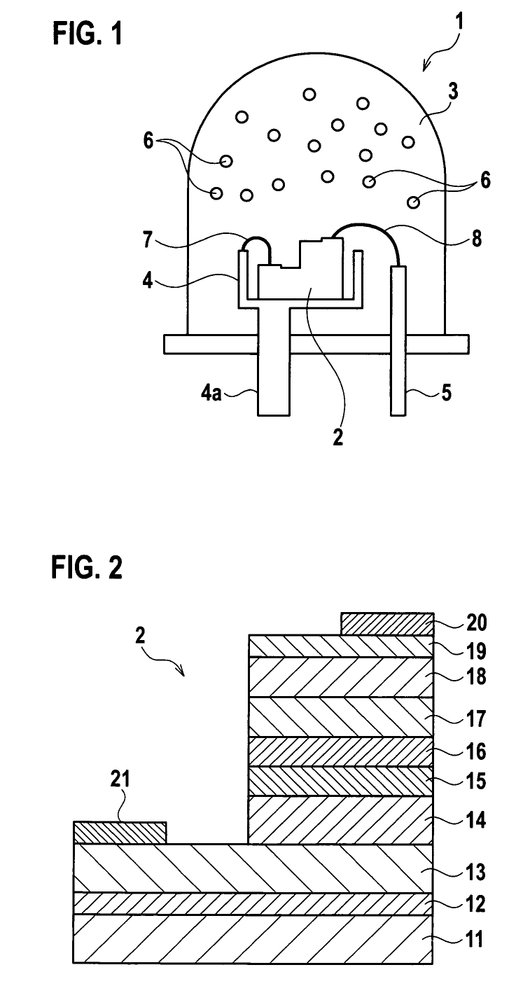

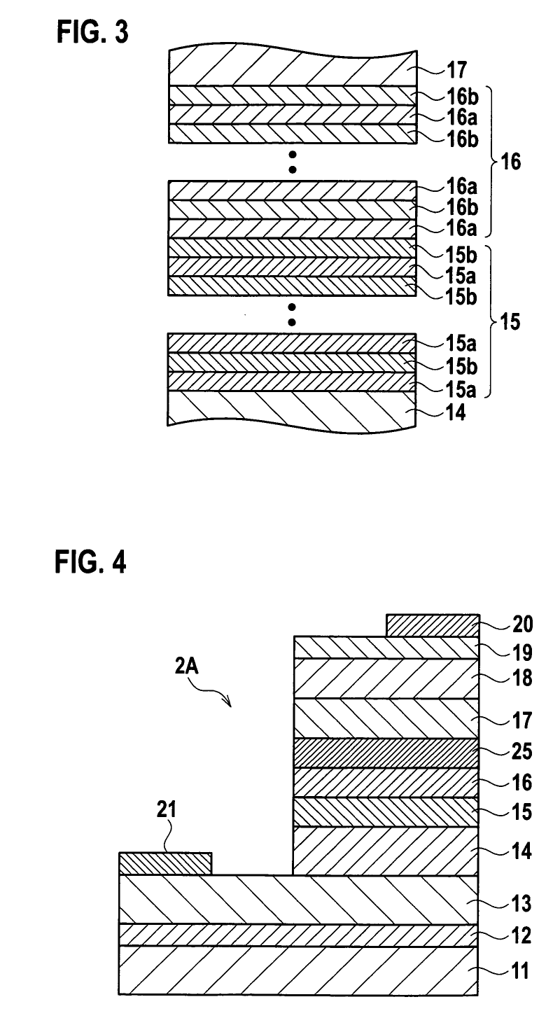

With reference to the drawings, a description is given below of a first embodiment of the present invention. FIG. 1 is a schematic view of a semiconductor white light emitting device according to the first embodiment of the present invention. FIG. 2 is a cross-sectional view of a semiconductor light emitting element, and FIG. 3 is a cross-sectional view of light emitting layers of the semiconductor light emitting element.

As shown in FIG. 1, the semiconductor white light emitting device 1 includes a semiconductor light emitting element 2, a package 3, a supporting member 4, and an external terminal 5.

As shown in FIG. 2, the semiconductor light emitting element 2 includes a buffer layer 12, an n-type contact layer 13, an n-type clad layer 14, a green light emitting layer 15, a blue light emitting layer 16, a p-type clad layer 17, a p-type contact layer 18, and a transparent electrode 19, which are sequentially stacked on a sapphire substrate 11. The semiconductor light emitting element 2 further includes a pair of p-side and n-side electrodes 20 and 21 for electrical connection to the outside.

The buffer layer 12 is composed an about 200 Å thick AlN layer. The N-type contact layer 13 is composed of an about 4 μm thick n-type GaN layer doped with Si as an n-type dopant. The layers 14 to 19 above the n-type contact layer 13 are etched so that a part of an upper surface of the n-type contact layer 13 is exposed. The n-type clad layer 14 is composed of an about 300 nm thick n-type AlGaN layer doped with Si as an n-type dopant. In the n-type clad layer 14, the ratio of Al to Ga is about 5/95 to 20/80.

The green light emitting layer 15 emits green light (wavelength: about 490 to 590 nm). As shown in FIG. 3, the green light emitting layer 15 has a MQW structure in which eight pairs of alternating well and barrier layers 15a and 15b are cyclically stacked. Each of the well layers 15a is composed of an about 3 nm thick InGaN layer in which a ratio of In to Ga is about 25/75 to 50/50. Each of the barrier layers 15b is composed of an about 10 nm thick AlGaN layer having a ratio of Al to Ga of not more than about 25/75.

The blue light emitting layer 16 emits blue light (wavelength: about 430 to 490 nm). As shown in FIGS. 2 and 3, the blue light emitting layer 16 is formed so as to be continuous to the green light emitting layer 15 on a light outgoing side of the green light emitting layer 15. The blue light emitting layer 16 has a MQW structure in which eight pairs of alternating well and barrier layers 16a and 16b are cyclically stacked. Each of the well layers 16a is composed of an about 3 nm thick InGaN layer in which a ratio of In to Ga is about 10/90 to 25/75. Each of the barrier layers 16b is composed of an about 10 nm thick AlGaN layer having a ratio of Al to Ga of not more than about 25/75.

The p-type clad layer 17 is composed of an about 100 nm thick p-type AlGaN layer doped with Mg as a p-type dopant. In the p-type clad layer 17, a ratio of Al to Ga is about 5/95 to 20/80. The p-type contact layer 18 is composed of an about 200 nm thick p-type GaN layer doped with Mg as a p-type dopant.

The transparent electrode 19 is composed of an about 300 nm thick ZnO layer capable of transmitting light emitted from the green and blue light emitting layers 15 and 16.

The p-side electrode 20 has an about 3000 nm thick stacking structure of Ti/Au which is in ohmic contact to the transparent electrode 19. The n-side electrode 21 is in ohmic contact to the exposed part of the upper surface of the n-type contact layer 13. The n-side electrode 21 has an about 2500 nm stacking structure of Al/Ti/Pt/Au.

The package 3 is made of synthetic resin capable of transmitting light and protects the semiconductor light emitting element 2. In the package 3, phosphors 6 capable of converting light with a wavelength not longer than that of blue light into red light (wavelength: about 590 to 780 nm). The phosphors 6 convert light with a wavelength not longer than that of blue light emitted from the blue light emitting layer 16 into red light. Such phosphors 6 can be (Ca, Sr, Ba)S:Eu₂₊, (Ca, Sr, Ba)₂Si₅N₈:Eu 2+, CaAlSiN₃:Eu₂₊, or the like.

The supporting member 4 supports the semiconductor light emitting element 2 and is composed of a conductor. The supporting member 4 is connected to the n-side electrode 21 through a wire 7 for electrical connection between the n-side electrode 21 of the semiconductor light emitting element 2 and the outside through an external terminal 4a.

The external terminal 5 is made of a conductor and electrically connects the p-side electrode 20 of the semiconductor light emitting element 2 to the outside through a wire 8.

Next, a description is given of an operation of the aforementioned semiconductor white light emitting device 1.

When the semiconductor white light emitting device 1 is externally supplied with current through the external terminals 4a and 5, holes are injected from the p-side electrode 20, and electros are injected from the n-side electrode 21. The holes are then injected into the blue and green light emitting layers 16 and 15 through the transparent electrode 19, p-type contact layer 18 and p-type clad layer 17, and the electrons are injected into the green and blue light emitting layers 15 and 16 through the n-type contact layer 13 and n-type clad layer 14. Some of the holes and electrons are combined in the blue light emitting layer 16 to emit blue light. The remaining holes and electrons are combined in the green light emitting layer 15 to emit green light.

The emitted blue light is transmitted through the p-type clad layer 17, p-type contact layer 18, and transparent electrode 19 and then incident to the package 13. Part of the blue light incident to the package 3 is radiated to the outside without being changed, and the other part thereof is converted into red light by the phosphors 6 and radiated to the outside.

The emitted green light is transmitted through the blue light emitting layer 16, p-type clad layer 17, p-type contact layer 18, and transparent electrode 19 and then incident to the package 3. Herein, the band gap of the blue light emitting layer 16 is larger than that of the green light emitting layer 15, and the green light incident to the blue light emitting layer 16 is transmitted through the blue light emitting layer 16 without being absorbed by the same. The green light incident to the package 3 is transmitted through the package 3 without being converted into red light by the phosphors 6 and radiated to the outside as green light.

The blue, green, and red are thus radiated to the outside to be mixed into white light.

Next, a description is given of a method for manufacturing the aforementioned semiconductor white light emitting device.

First, the sapphire substrate 11 is introduced into an MOCVD apparatus, and temperature of the substrate 11 is set to about 500 to 1100° C.

Next, trimethylaluminum (hereinafter, referred to as TMA) and ammonium are supplied with carrier gas (H₂ gas) to form the buffer layer 12 composed of AlN on the sapphire substrate 11.

Next, trimethylgallium (hereinafter, TMG), ammonium, and silane are supplied with the carrier gas to form the n-type contact layer 13 composed of an n-type GaN layer doped with silicon.

Next, TMG, TMA, ammonium, and silane are supplied with the carrier gas to form the n-type clad layer 14 composed of an n-type AlGaN layer doped with silicon.

Next, TMG, trimethylindium (hereinafter, TMI), and ammonium are supplied with the carrier gas to form a first one of the well layers 15a composed of an InGaN layer. Subsequently, the TMI is changed to TMA to form a first one of the barrier layers 15b composed of an AlGaN layer. Such a process is repeated to alternately grow eight pairs of the well and barrier layers 15a and 15b, thus forming the green light emitting layer 15.

Next, TMG, TMI, and ammonium are supplied with the carrier gas to form a first one of the well layers 16a composed of an InGaN layer. Herein, the flow rate of TMI is set smaller than that in the case of forming the well layers 15a composed of the InGaN layers in the aforementioned green light emitting layer 15. Thereafter, TMI is changed to TMA to form a first one of the barrier layers 16b composed of an AlGaN layer. Such a process is repeated to alternately grow eight pairs of the well and barrier layers 16a and 16b, thus forming the blue light emitting layer 16.

Next, TMG, TMA, ammonium, and biscyclopentadienylmagnesium (hereinafter, Cp₂Mg) are supplied with the carrier gas to form the p-type clad layer 17 composed of a p-type AlGaN layer doped with Mg.

Next, TMG, ammonium, and Cp₂Mg are supplied with the carrier gas to form the p-type contact layer 18 composed of a p-type GaN layer doped with Mg.

Next, dimethylzinc (Zn(CH₃) 2) and tetrahydrofrane (C₄H₈O) are supplied with the carrier gas to form the transparent electrode 19 composed of a ZnO layer.

Next, the layers from the transparent electrode 19 to n-type glad layer 14 are partially removed by etching so that a part of the n-type contact layer 13 is exposed.

Next, the p-side and n-side electrodes 20 and 21 are individually formed, and then the obtained product is divided into each semiconductor light emitting element, thus completing the semiconductor light emitting element 2.

Next, the semiconductor light emitting element 2 is attached to the supporting member 4 and is wire-bonded to the supporting member 4 and external terminal 5. Eventually, the semiconductor light emitting element 2 and the like are covered with the package 3 containing the phosphors 6, thus completing the semiconductor white light emitting device 1.

In the semiconductor white light emitting device 1 according to the first embodiment, as described above, the semiconductor light emitting element 2 is provided with the green and blue light emitting layers 15 and 16 each having a ratio of In smaller than that of a light emitting layer capable of emitting red light. Accordingly, the light emitting layers 15 and 16 can be increased in crystallinity, and the emission intensities of green and blue light can be easily increased to desired emission intensities. It is therefore possible to prevent white light from being biased to a certain color and increase the amount of white light.

Since the green and blue light emitting layers 15 and 16 are provided, white light can be radiated only by blending one type of the phosphors 6 emitting red light into the package 3. Accordingly, there is no need to control the ratio of phosphors unlike the case where two types of phosphors to emit two types of red and yellow-green light are blended in the package, and the phosphors 6 can be uniformly blended in the package 3 easily. Furthermore, applying the phosphors 6 capable of emitting red light upon receiving light with a wavelength not longer than that of blue light allows the amount of red light to be controlled more easily than the case of applying phosphors emitting red light upon receiving two types of light (for example, ultraviolet and blue light). It is therefore possible to prevent white light from being biased to a certain color.

Since the blue light emitting layer 16, which has a band gap larger than that of the green light emitting layer 15, is formed on the light outgoing side of the green light emitting layer, blue light, which can be absorbed by the green light emitting layer 15, is radiated to the outside without being transmitted through the green light emitting layer 15, and the amount of blue light can be therefore easily controlled.

### Second Embodiment

Next, with reference to the drawings, a description is given of a semiconductor white light emitting device according to a second embodiment obtained by partially modifying the semiconductor light emitting element of the semiconductor white light emitting device of the first embodiment. FIG. 4 is a cross-sectional view of the semiconductor light emitting element according to the second embodiment. Similar components to those of the first embodiments are given same reference numerals.

As shown in FIG. 4, the semiconductor light emitting element 2A includes an ultraviolet light emitting layer 25 formed between the blue light emitting layer 16 and p-type clad layer 17. The ultraviolet light emitting layer 25 emits ultraviolet light (wavelength: about 100 to 430 nm). The ultraviolet light emitting layer 25 has an MQW structure in which eight pairs of alternating well and barrier layers (not shown) are stacked cyclically. Each of the well layers is composed of an about 3 nm thick InGaN layer whose ratio of In is less than that of the InGaN layers constituting the well layers 16a of the blue light emitting layer 16. Specifically, in the well layers of the ultraviolet light emitting layer 25, the ratio of In to Ga is about 0 to 15/85. Each of the barrier layers of the ultraviolet light emitting layer 25 is composed of an about 10 nm thick AlGaN layer having a ratio of Al to Ga of not more than 25/75.

In the second embodiment, the phosphors 6 mixed in the package 3 are capable of emitting red light upon receiving light having a wavelength not longer than that of the ultraviolet light. Such phosphors 6 can b eY₂O₃S:Eu²⁺, (Ca, Sr, Ba)₂Si₅N₆:Eu²⁺, CaAlSiN₃:Eu 2+, La₂O₂S:Eu²⁺, or the like.

Next, a description is given of a method for forming the ultraviolet light emitting layer 25. After the blue light emitting layer 16 is formed, TMG, TMI, and ammonium are supplied with the carrier gas to form a first one of the well layers composed of an InGaN layer. Herein, the flow rate of TMI is set smaller than that in the case of forming the well layers 16a of the blue light emitting layer 16, which are composed of InGaN layers. Thereafter, TMI is changed to TMA to form a first one of the barrier layers composed of an AlGaN layer. Such a process is repeated to alternately grow eight pairs of the well and barrier layers to form the ultraviolet light emitting layer 25.

In the semiconductor white light emitting device according to the second embodiment, when the semiconductor light emitting element 2A is supplied with current, the green, blue, and ultraviolet light emitting layers 15, 16, and 25 emit green, blue, and ultraviolet light, respectively. The emitted green and blue light are transmitted through the semiconductor layers 17 to 19 and package 3 to be radiated to the outside. On the other hand, after being transmitted through the semiconductor layers 17 to 19 and incident to the package 3, the ultraviolet light is converted by the phosphors 6 into red light and then irradiated to the outside as red light. The red, green, and blue light are therefore mixed and radiated to the outside as white light.

As described above, the semiconductor white light emitting device according to the second embodiment includes the semiconductor light emitting element 2A having the green and blue light emitting layers 15 and 16 and the phosphors 6 emitting red light and accordingly can provide similar effects to those of the first embodiment.

Furthermore, since the ultraviolet light emitting layer 25 is provided for the semiconductor light emitting element 2A and the phosphor 6 capable of emitting red light upon receiving light with a wavelength not longer than that of ultraviolet light is applied, red light can be emitted only by ultraviolet light which does not affect white light. The light emitted from the green and blue light emitting layers 15 and 16 can be radiated to the outside without being converted. This can facilitate control of the amounts of red, green and blue light, thus preventing the imbalance between colors of white light.

Moreover, since the ultraviolet, blue, and green light emitting layers 25, 16, and 15 are arranged in descending order of the band gaps from the light outgoing side, light emitted from the light emitting layers 25, 16, and 5 and propagated to the light outgoing side are not absorbed by the light emitting layers 25, and 16, and 15. This can facilitate control of the amounts of ultraviolet, blue, and green light.

Hereinabove, the present invention is described in derail using the embodiments but not limited to the embodiments described in this specification. The scope of the present invention is determined based on the scope of claims and their equivalents. In the following, a description is given of modifications obtained by partially modifying the aforementioned embodiments.

For example, the materials constituting the individual layers of the aforementioned semiconductor light emitting layers 2 and 2A and phosphor 6 can be properly changed.

Moreover, the order of the light emitting layers 15, 16, and 25 of the semiconductor light emitting elements 2 and 2A can be properly changed. For example, when the green light emitting layer 15 is formed on the light outgoing side of the blue light emitting layer 16, green light can be also emitted by blue light incident in the green light emitting layer 15. This can increase the emission intensity of the green emitting layer 15, which has a ratio of In larger than that of the blue light emitting layer 16 and therefore has lower emission intensity.

The numbers of the pairs of well and barrier layers in the light emitting layers 15, 16, and 25 can be properly changed between 1 to 10 pairs, for example. Moreover, the light emitting layers 15, 16, and 25 may have different numbers of pairs of well and barrier layers. For example, to increase the ratio of blue light, the blue light emitting layer is configured to include eight pairs of well and barrier layers while the green light emitting layer is configured to include four pairs of well and barrier layers.

Moreover, the sapphire substrate is used in the aforementioned embodiment, but another conductive substrate can be applied.

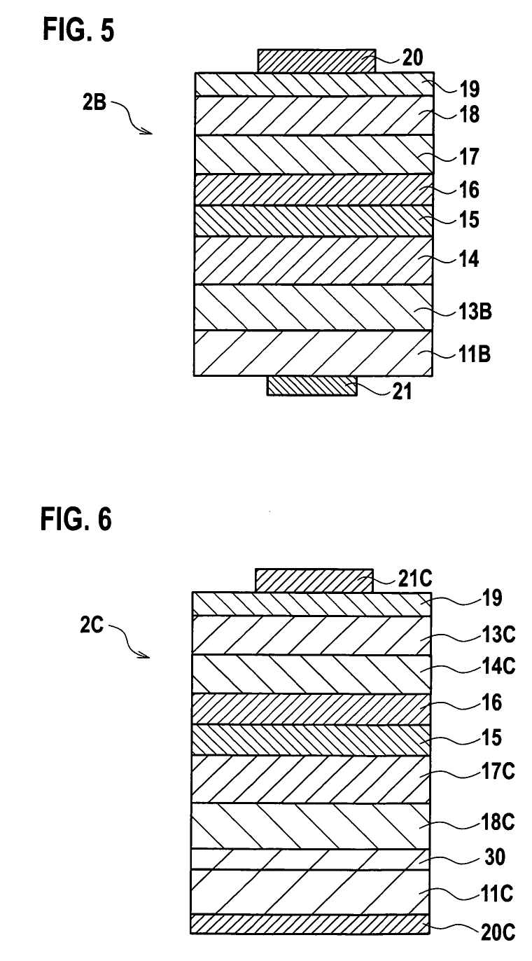

For example, the substrate can be an n-type GaN substrate. In this case, as shown in FIG. 5, the semiconductor light emitting element 2B includes an n-type contact layer 13B and the n-type clad layer 14, green light emitting layer 15, blue light emitting layer 16, p-type clad layer 17, p-type contact layer 18, and transparent electrode 19, which are sequentially stacked on an n-type GaN substrate 11B. The semiconductor light emitting element 2B further includes a p-side electrode 20 and an n-side electrode 21 formed on a lower surface of the n-type GaN substrate 11B. The n-type contact layer 13B is composed of an about 1 μm thick n-type GaN layer. The n-type contact layer 13B may be replaced with an n-type SiC substrate.

Moreover, the substrate may be a p-type Si substrate. In this case, as shown in FIG. 6, a semiconductor light emitting element 2C includes a reflecting layer 30, a p-type contact layer 18C, a p-type clad layer 17C, the green light emitting layer 15 and blue light emitting layer 16, an n-type clad layer 14C, an n-type contact layer 13C, and the transparent electrode 19, which are sequentially stacked on an p-type Si substrate 11C. The semiconductor light emitting element 2C further includes an n-side electrode 21C formed on an upper surface of the transparent electrode 19 and a p-side electrode 20C formed on a lower surface of the p-type Si substrate 11C. The reflecting layer 30 includes Ag/TiW/Pt stacked in a thickness of about several micrometers. Each of the p-type contact and clad layers 18C and 17C is composed of an about 300 nm thick p-type AlGaN layer. The n-type clad and contact layers 14C and 13C are composed of about 100 nm thick and 500 nm thick n-type AlGaN layers, respectively. The n-side and p-side electrodes 21C and 20C have the same structures as those of the p-side and n-side electrodes 21 and 20, respectively. The p-type Si substrate may be replaced with an n-type Si substrate.

What is claimed is:

1. A semiconductor white light emitting device comprising:
a semiconductor light emitting element including a green light emitting layer and a blue light emitting layer which contain In; and
a phosphor capable of emitting red light.

2. The device of claim 1, wherein
the blue light emitting layer is formed on a light outgoing side of the green light emitting layer.

3. The device of claim 1, wherein
the green light emitting layer is formed on a light outgoing side of the blue light emitting layer.

4. The device of claim 1, wherein
the phosphor emits red light upon receiving light with a wavelength not longer than that of blue light.

5. The device of claim 1, wherein
the semiconductor light emitting element includes an ultraviolet light emitting layer.

6. The device of claim 5, wherein
the ultraviolet light emitting layer is formed on a light outgoing side of the blue and green light emitting layers.

7. The device of claim 5, wherein
the phosphor emits red light upon receiving light with a wavelength not longer than that of ultraviolet light.

8. The device of claim 1, further comprising
a package which is composed of synthetic resin capable of transmitting light with the phosphor blended and covers the semiconductor light emitting element.

9. The device of claim 1, wherein
the semiconductor light emitting element includes a conductive substrate.

10. The device of claim 9, wherein
the semiconductor light emitting element includes an electrode formed on a surface of the substrate opposite to the light emitting layers.

11. A method for manufacturing a semiconductor white light emitting device, the method comprising:
a step of forming a semiconductor light emitting element including a green light emitting layer and a blue light emitting layer which contain In; and
a step of covering the semiconductor light emitting element with a package which is made of synthetic resin capable of transmitting light in which a phosphor capable of emitting red light is blended.

12. The method of claim 11, wherein
the blue light emitting layer is formed after the green light emitting layer is formed.

13. The method of claim 11, wherein
the green light emitting layer is formed after the blue light emitting layer is formed.

14. The method of claim 11, wherein in the step of forming the semiconductor light emitting element, an ultraviolet light emitting layer is formed.

15. The method of claim 14, wherein
the ultraviolet light emitting layer is formed after the blue and green light emitting layers are formed.
